(19) United States
(12) Patent Application Publication
(10) Pub. No.: US 2006/0284282 A1
(43) Pub. Date: Dec. 21, 2006

(54) Heterjunction bipolar transistor with tunnelling mis emitter junction

(75) Inventor: Shaun Joseph Cunningham, Lane Cove (AU)

Correspondence Address: BANNER & WITCOFF, 1001 G STREET N W, SUITE 1100, WASHINGTON, DC, 20001, US

(73) Assignee: EpiTactix Pty Ltd, Marsfield,NSW (AU)

(21) Appl. No.: 10/570,310

(22) PCT Filed: Sep. 2, 2004
(86) PCT No.: PCT/AU04/01184

§ 371 Date: Mar. 2, 2006

Related U.S. Application Data
(60) Provisional application No. 60/499,785, filed on Sep. 2, 2003.

(51) Int. Cl. H01L 27/082

(52) U.S. Cl. 257/565

(57) ABSTRACT

A manufacturing method and structure for a MIS Heterojunction Bipolar Transistor (HBT) is provided including a GaAs substrate which has a collector region; a base layer coupled to the collector region; the ultra-thin insulating layer including a rare earth oxide coupled to the base layer; and an emitter structure including metal layers coupled to the ultra-thin insulating layer.

### FIELD OF INVENTION

The present invention relates generally to integrated circuits. More particularly, the invention provides a manufacturing method and structure for a metal-insulator-semiconductor (MIS) transistor structure comprising compound semiconductor material. It will be appreciated, however, that there can be many variations, modifications, and alternatives. It will be convenient to hereinafter describe the invention in relation to a MIS Heterojunction Bipolar Transistor (HBT) comprising a GaAs substrate, however it should be appreciated that the present invention Is not limited to that use only.

### BACKGROUND

The inventor has identified-the following background and related art. For years, device designers have appreciated the importance of bandgap engineering in designing transistor devices for high performance applications. Bandgap engineering is known as the art of creating semiconductor junctions from materials which have similar crystal structures but different intrinsic electron energy levels. Junctions formed from different materials are commonly referred to as heterojunctons. Electron transport across these junctions can be enhanced by the appropriate selection of materials.

Compound semiconductor material systems based on gallium arsenide (GaAs), indium phosphide (InP) and other elemental compounds may be used as the basis an which heterojunctions can be formed and from which ultra-high performance transistors can be built.

Single crystal boules made from materials such as GaAs may be grown and sliced to form wafer substrates. Layers of different materials may be epitaxially grown on the surface of these wafers and are then patterned by etching to form devices such as Heterojunction Bipolar Transistors (HBTs). These devices are made from layers of different materials which are doped with impurities to make them electron-rich (n-type) or electron-deficient (p-type). In this way, desirable p-n junctions may be formed which enhance charge carrier transport within the transistor.

On gallium arsenide wafers for example, conventional heterojunctions may be formed using layers of materials such as Indium gallium phosphide (InGaP), indium gallium arsenide (InGaAs), aluminium gallium arsenide (AlGaAs) and aluminium arsenide (AlAs). On indium phosphide wafers, heterojunctions may be formed using indium gallium arsenide material. In each case the bandgap and energy band offset of the heterojunction may be controlled by changing the relative proportions of elemental constituents of the material. Although there have been significant improvements in conventional devices, many limitations still exist and additional improvement is desired.

FIG. 1 shows a typical layer structure used to form conventional npn GaAs HBTs.

Typically, layer structures are devised which not only achieve desired electronic properties of a transistor but which also offer wafer processing advantages such as selective etching. Selective etching techniques allow one layer to be removed in certain areas of the wafer without affecting underlying or surrounding layers. This is particularly important in controlling etching processes which need to stop abruptly on the boundaries of layers which might be very thin (e.g. 100-500 angstroms).

Transistor performance is not only determined by the choice of layer material but also layer thickness. Selection of layer thickness sometimes involves a compromise between certain transistor parameters. For example, in conventional devices, high speed devices often need thin layers to shorten electron transit times while high power devices generally need thick layers to withstand high voltages. Therefore, in general, it is not possible to completely optimise a conventional transistor for both high speed and high operating voltage. Typical layer thicknesses for prior art npn GaAs/InGaP HBT devices are also shown in FIG. 1.

Transistor performance is also affected by device geometry. For example it is advantageous to make devices as small as possible in order to maximise their operating frequency. As devices become smaller, their maximum operating frequency increases because both junction capacitance and spreading resistance are reduced by making the device smaller. Spreading resistance is the resistance encountered between the lateral base contacts and the central, active area of the device due to the resistivity of typical semiconductor materials and the physical displacement of the contacts.

FIG. 2 provides an example of a certain conventional device structure.

The emitter mesa structure 200 is comprised of four semiconductor layers:
layer 204 forms the emitter side of the emitter/base heterojunction and is made of a material which has different etching characteristics than the adjacent layers,
layer 203 is a buffer/spacer layer,
layer 202 is a graded structure which varies from the crystal lattice spacing of GaAs at the interface to layer 203 to the lattice spacing of InGaAs (50% Ga) at the interface to layer 201, and
layer 201 which allows a non-alloyed ohmic contact to be made to the emitter structure.

The emitter mesa 200 is formed by firstly depositing and patterning emitter contact layer 205 on the surface of a wafer which has a layer structure as shown in FIG. 1. Nest, emitter layers 201, 202 and 203 are etched away except where protected by the emitter contact 205. Etching stops at layer 204 because it is unaffected by the etchant used to remove layers 201-203. However etching continues horizontally and helps to produce undercut sidewalls of the emitter mesa structure.

Layer 204 is then removed using an etchant which does not affect the underlying base layer 207. In this way, the emitter mesa can be formed without degrading the very thin base layer 207.

The base contact layer 206 is deposited over the entire base and emitter area using a directional deposition process. Since the sidewalls of the emitter mesa structure are under-cut, the emitter contact layer 205 creates a shadow which allows the base contact layer 206b to be deposited in close proximity to the emitter without touching it, except harmlessly on top of the emitter ohmic, 206a. In this fashion, conventional devices achieve self alignment of base emitter junction connections thereby enhancing device performance by minimising base spreading resistance.

A major problem is often encountered in the conventional process, however. The etching profile of the emitter mesa is determined by the crystalline structure of the emitter layers. This can cause the emitter to be etched differently in X and Y dimensions as shown in FIG. 3.

The side view of the emitter mesa looking along the Y axis 301 shows etching profile 303 caused by the crystal orientation in this dimension. The emitter mesa is undercut on these sides with respect to the emitter contact This creates a shadow during base contact 302 deposition which ensures separation 304 from the emitter mesa.

The side view of the same emitter mesa looking along the X axis 311 shows a different etching profile 313 caused by the crystal orientation. If the emitter contact bonds to the top surface well, it can prevent the mesa from being etched along the crystal plane originating from this point. This means that the sidewalls of the emitter mesa can protrude outside the perimeter of the emitter contact such that the base contact 312 comes into contact with the emitter mesa causing unwanted parasitic junctions 314 to form. These parasitic junctions are a significant problem which limits device and circuit yields in the conventional HBT fabrication.

Manufacturers of conventional HBTs also experience problems in making connections to emitter contacts because they are vertically displaced from the insulating plane on which metal interconnects are deposited on the wafer, as shown in FIG. 4.

In order to electrically isolate devices from each other on the conventional wafer, epitaxial layers are sometimes etched to form mesa structures on the underlying semi-insulating substrate which are physically isolated from each other. This results in a structure similar to that shown in FIG. 4a.

Emitter mesa 401 rests on base-collector mesa 402 which in turn rests on semi-insulating substrate 403. Connections to the emitter ohmic contact 409 are made by metal deposited in the form of an arch 404. This arch structure is formed as either an “air bridge” or as a similar structure supported by an underlying polymer (not shown). The arch is positioned to achieve a horizontal displacement from the wall of the transistor mesas to provide electrical isolation while spanning the vertical displacement from the emitter ohmic to the surface of the semi-insulating substrate. These connections can be partially unsupported 407 and fragile which limits device fabrication yields.

Implantation is also used to isolate transistors as shown in FIG. 4b. Instead of etching away unwanted base-collector mesa layers, certain elements are implanted into redundant portions of the base and collector layers 418 to make them insulating. This reduces the vertical profile of the transistors and lessens the problems described above, but does not overcome them.

Because the emitter interconnect metal 404/414 tends to be thick (e.g. 2-3 microns) to strengthen the resulting structure, it is difficult to pattern this layer to form sub-micron-sized connections to the emitter ohmic 409/419. The emitter ohmic 409/419 needs to be larger than the foot of the interconnect arch 404/414 to allow for possible alignment errors during fabrication. The emitter arch structure therefore sets a limit below which the emitter dimensions cannot be decreased. This limits conventional device scaling to around 1 micron emitter widths and prevents improvement of transistor high frequency performance by making devices smaller.

Designers of bipolar transistors continually strive to increase device current gain which leads to increased efficiency and lower noise figures. Current gain is defined as the ratio of collector to base current and may be increased by increasing emitter efficiency.

In conventional compound semiconductor transistors, surface leakage effects around the periphery of the base-emitter junction (e.g. caused by high surface recombination velocities) increase base-emitter leakage current and decrease current gain. As devices are made smaller to increase their operating frequency, the ratio of emitter area to emitter periphery decreases. Surface leakage currents at the emitter periphery therefore represent a larger proportion of the total emitter current and hence current gain is reduced. As such transistors are made smaller to enhance their high frequency performance, their gain, efficiencies and noise figures suffer.

It is therefore desirable to devise a means of producing transistors which have high gain and low noise characteristics at higher frequencies.

Conventional HBT devices approach this challenge by using special emitter structures (heterojunctions) which increase intrinsic current gain. These structures employ wide bandgap materials for the emitter layer which block hole injection from the base into the emitter and therefore increase intrinsic current gain. HBTs made on GaAs substrates use either AlGaAs or InGaP for this purpose. The selective etching properties of these materials also allows “ledges” of these materials 213 to be left around the bottom of the emitter mesa as shown in FIG. 2. Since this layer is very thin, it becomes fully depleted of charge carriers and therefore acts as a barrier which prevents “unproductive” emitter surface current from reaching the base.

The complexity of the processes required to form the emitter mesa and surrounding ohmic and interconnect structures significantly compromises device and circuit fabrication yield. For example, circuits containing thousands of HBTs typically have less than 50% yield.

The present inventor further realised that a number of developments had been made in relation to semiconductor design and production techniques. In this regard, the inventor has also become aware of the following.

Recently, a paper titled “Single Crystal Gd₂O₃ Films Epitaxially Grown on GaAs—A New Dielectric for GaAs Passivation”, by M. Hong et al, Mat. Res. Soc. Proc., Vol. 535, 1999, has described a new passivation approach for the first time. For many years, researchers had used a combination of gallium oxide (Ga₂O₃) and gadolinium oxide (Gd₂O₃). In attempting to grow insulating films on GaAs. The paper described that Gd₂O₃ films can be epitaxially grown on GaAs as mono-crystalline structures. This finding is unexpected because of the large mismatch between the lattice constants of the two materials (10.8 and 5.6A° for Gd₂O₃ and GaAs respectively).

Another paper titled “Gadolinium Oxide and Scandium Oxide:Gate Dielectrics for GaN MOSFETs” by B. P. Gila, phys. stat. sol. (a) 188, No. 1, 239-242, 2001 describes the use of Gd₂O₃ as a passivation layer on gallium nitride.

The concept of using metallic emitter structures for silicon bipolar transistors is known. A description of the fundamental principles of this class of transistor can be found in the paper: “Super-Gain Silicon MIS Heterojunction Emitter Transistors” M. A. Gin, et al, IEEE Electron Device Letters, vol. EDL-4, No. 7, pp 225-227, July 1983. The emitters of these devices are made from low work-function metals such as magnesium, deposited on top of ultra thin silicon dioxide insulating layers approximately 20 angstroms thick.

The band diagram of the emitter-base junction for this type of transistor is shown under zero bias conditions in FIG. 5. A low work function metal is chosen for the emitter such that electrons can tunnel from the metal's conduction band, through the insulating layer and into the p-type base layer, forming a pseudo-n-type inversion layer. Because of the band structure of this type of junction, emitter-base current flow is predominantly due to electron tunnelling from emitter to base and hole injection from base to emitter is effectively blocked. This enhances transistor current gain and reduces sources of noise generation. Silicon transistors with current gains as high as 25,000 have been reported.

For MIS transistors to function properly, it is imperative that the material chosen for the ultra-thin, insulator is able to passivate the underlying semiconductor surface and eliminate surface states which would distort band structure and impede electron transport. Although it has been known that silicon dioxide forms an excellent passivation layer on silicon, an equivalent passivation material for compound semiconductors such as gallium arsenide has remained unknown for many years.

Any discussion of documents, devices, acts or knowledge in this specification is included to explain the context of the invention. It should not be taken as an admission that any of the material forms a part of the prior art base or the common general knowledge in the relevant art in Australia or elsewhere on or before the priority date of the disclosure and claims herein.

An object of the present invention is to provide an improved MIS HBT device and manufacturing process.

A further object of the present invention is to alleviate at least one disadvantage associated with the prior art.

### SUMMARY OF THE INVENTION

According to the present invention, improved integrated circuits are provided. More particularly, the invention provides a method and structure for a high performance heterojunction bipolar transistor which is suited to compound semiconductor material systems such as gallium arsenide and which utilises an emitter junction formed from a plurality of metal layers and a plurality of ultra-thin insulating layers. The metal layers chosen have work-functions which form a tunnelling Metal-Insulator-Semiconductor (MIS) emitter junction when deposited on top of an ultra-thin insulating layer. The insulating layer may be made from a rare-earth oxide such as gadolinium oxide (Gd₂O₃) which is epitaxially grown on a compound semiconductor substrate and possibly covered with a second ultra-thin insulating layer.

In a specific embodiment, the invention provides a metal-insulator-semiconductor transistor structure comprising III/V compound semiconductor material. The structure comprises a collector region; a base layer coupled to the collector region; an ultra-thin insulating layer comprising a rare earth oxide coupled to the base layer; and an emitter structure comprising a plurality of metal layers coupled to the ultra-thin insulating layer.

In an alterative specific embodiment, the invention provides a method for manufacturing a metal-insulator-semiconductor transistor structure comprising III/V compound semiconductor material. The method comprises providing a semiconductor substrate having a surface region. The method also comprises forming a collector region within a portion of the substrate and forming a base layer overlying the collector region. The method comprises forming a rare earth oxide layer overlying the base layer and selectively depositing an emitter layer and emitter cap layer using a single process operation overlying the rare earth oxide. The method comprises selectively removing at least a portion of the emitter layer while undercutting a portion of the emitter cap layer to reduce a width of the emitter layer. The method comprises selectively depositing a base contact layer over both base and emitter regions to form a base contact. The base contract is self-aligned to the emitter structure.

In yet an alternative embodiment, the invention provides a method for manufacturing a metal-insulator-semiconductor transistor structure comprising III/V compound semiconductor material. The method comprises providing a semiconductor substrate and forming a collector region within the substrate. The method also comprises forming a base layer overlying the collector region and forming a rare earth oxide layer overlying the base layer. The method comprises selectively implanting the substrate with an ion which renders it insulating and forms isolation regions and selectively depositing an emitter layer and emitter cap layer in a single process operation overlying the rare earth oxide. The method also comprises selectively removing at least a portion of the emitter layer while undercutting a portion of the emitter cap layer to reduce a width of the emitter layer and selectively depositing a base contact layer over both base and emitter regions to form a base contact which is self-aligned to the emitter structure.

Still further in another embodiment, the invention provides a method for manufacturing a MIS HBT transistor structure comprising III/V compound semiconductor material. The method comprises providing a semiconductor substrate and forming a blanket collector region within the substrate. The method also comprises forming a blanket base region overlying the collector region and forming a blanket rare earth oxide overlying the base region. The method may then further comprise selectively implanting one or more regions to form one or more isolation regions.

Still further in another embodiment, the invention provides a method for manufacturing a MIS HBT transistor structure comprising III/V compound semiconductor material. The method comprises providing a semiconductor substrate and forming a collector region within the substrate. The method also comprises forming a base region overlying the collector region and forming a rare earth oxide overlying the base region. The method comprises forming a blanket emitter layer overlying the rate earth oxide and forming a blanket emitter cap layer overlying the emitter layer. A step of patterning at least the blanket emitter cap layer to define a first portion of one or more emitter structures and to define a second portion of one or more interconnect structures may also be included.

The present invention, in another aspect, also provides a fabrication means for producing high performance MIS HBT transistors on compound semiconductor substrates. The fabrication process allows emitter structures to be produced with sub-micron dimensions by utilising the metallic emitter layers as a means of connecting the device to other components. This eliminates the need for an additional metal interconnect layer to the emitter which prevents emitter size reduction in conventional devices processes.

According to a specific embodiment, the figures of merit used to describe a transistor's high frequency performance are Fₜ and Fₘₐₓ Fₜ is the frequency where the current gain of an HBT drops to unity. Fₘₐₓ is the frequency where the maximum available power gain of the device drops to unity. Conventional HBT devices made from gallium arsenide typically have Fₜ and Fₘₐₓ around 50, and 70 GHz respectively. High performance HBTs might have Fₜ and Fₘₐₓ in excess of 100 GHz and ultra-high performance HBTs might have Fₜ and Fₘₐₓ in excess of 150 GHz. Other definitions may also be used.

In essence, the present invention stems from the realisation that because many rare earth elements have very similar atomic structure, it is expected that a wide range of rare-earth oxides are also able to be used as passivation layers for various compound semiconductor materials. It is expected that rare earth elements that form trivalent oxides of the form X₂O₃ (where X is a rear earth element) are suitable for this purpose. Subsequent exploration of the applications of these rare earth oxides has been exclusively focused on the development of gate dielectric layers for compound semiconductor MOSFETs. In these devices the rare earth oxides are deliberately made thick enough to prevent electrons tunnelling through them. To the inventor's knowledge, the benefit of these new materials in compound semiconductor MIS HBT devices, where the rare earth oxide is thin enough for electrons to tunnel through, is unknown in the prior art.

The discovery of the properties of gadolinium oxide when used as a gate dielectric in compound semiconductor MOSFET devices demonstrates that it passivates materials such as gallium arsenide very well. The applicants believe that this dielectric is also suitable for use in other devices such as MIS bipolar transistors where surface passivation is equally important. The bandgap of the insulating material used to form a MIS junction is an important material parameter. If the bandgap is too large e.g. 9 electron volts as for silicon dioxide, the barrier height of the insulator-semiconductor interface reduces electron tunnelling probabilities and junction performance degrades. On the other hand, if the insulator bandgap is too narrow, it is ineffective in stoping unproductive current flow, such as hole current flow from base to emitter in an npn bipolar transistor. Accordingly, it is considered advantageous to use an insulator with a bandgap greater than approximately 3 electron volts

Furthermore, the invention stems from the realisation that in conventional compound semiconductor HBT, the high surface recombination velocity of electrons in the base-emitter junction creates leakage currents which degrade transistor current gain and increase noise figure. Because the present invention utilises a low-work-function metallic emitter and an insulating barrier through which electrons tunnel, the problems associated with surface leakage currents of conventional devices are eliminated and electrons in the emitter uniformly tunnel through to the base. The MIS structure also enhances the ratio of electron current to hole current flowing from emitter to base because of the favourable band structure of the junction. The resultant MIS structure of the present invention therefore has higher current gain and lower noise figure than conventional compound semiconductor bipolar transistors. The present invention therefore enables compound semiconductor HBT transistors to be manufactured such that they may be reduced in size without compromising their current gain and noise figure. The benefits of this MIS structure could not be realised in prior art compound semiconductor bipolar transistors because a suitable insulating material for the MIS junction was unknown.

Other aspects and preferred aspects are disclosed in the specification and/or defined in the appended claims, forming a part of the description of the invention.

The present invention has been found to result in a number of advantages, such that the resulting MIS HBT device and manufacturing process:
simplifies fabrication requirements and increases device and circuit yields,
allows devices to be fabricated with sub-micron emitter widths,
improves reproducibility of emitter-base junctions, and
enhances electron transport through the device and improves emitter efficiency, current gain, noise figure and maximum operating frequency. Depending upon the embodiment, one or more of these benefits may be achieved.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

This and other embodiments, aspects, advantages and features of the present invention will be set forth in part in the description which follows, and in part will become apparent to those skilled in the art by reference to the following description of the invention and referenced drawings or by practice of the invention. The aspects, advantages and features of the invention are realized and attained by means of the instrumentalities, procedures and combinations particularly pointed out in the appended claims.

### BRIEF DESCRIPTION OF THE DRAWINGS

Further disclosure, objects, advantages and aspects of the present application may be better understood by those skilled in the relevant art by reference to the following description of preferred embodiments taken in conjunction with the accompanying drawings, which are given by way of illustration only, and thus are not limitative of the present invention, and in which:

FIG. 1 is a simplified diagram of a conventional HBT device structure,

FIG. 2 is a simplified diagram of a GaAs/InGaP npn conventional HBT device,

FIG. 3 is a simplified diagram of a conventional emitter mesa etching profile,

FIGS. 4a and 4b are simplified diagrams of conventional HBT structures with implant isolation,

FIG. 5 is a band diagram of the emitter-base junction of a MIS bipolar transistor as known in the prior art,

FIG. 6 is an npn GaAs MIS HBT Layer Structure according to an embodiment of the present invention,

FIGS. 7a through 7c are simplified diagrams of devices according to an embodiment of the present invention,

FIGS. 8a through 8c are simplified diagrams of devices according to an embodiment of the present invention,

FIGS. 9a through 9c are simplified diagrams of devices according to an embodiment of the present invention.

FIG. 10 is a simplified diagram of an etch profile according to an embodiment of the present invention,

FIGS. 11a through 11b are simplified diagrams of devices according to an embodiment of the present invention, and

FIGS. 12a through 12c are simplified diagrams of devices according to an embodiment of the present invention.

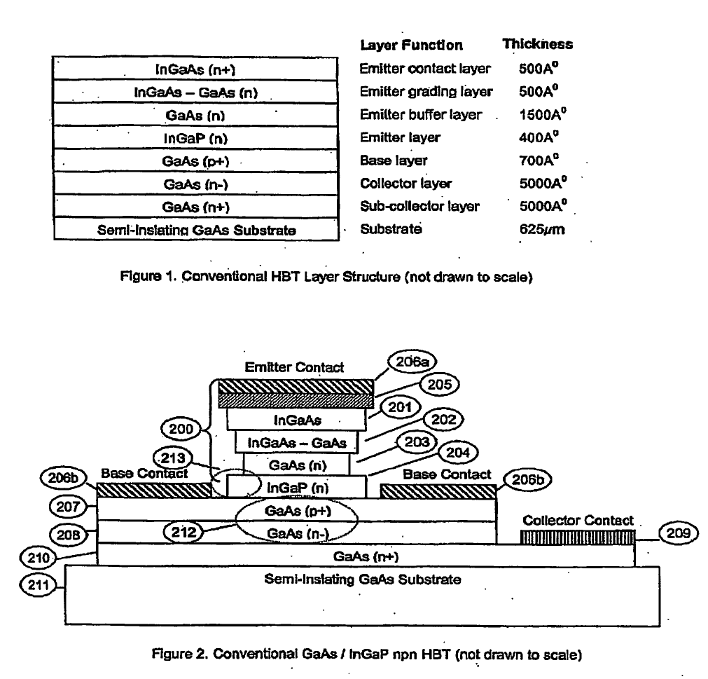

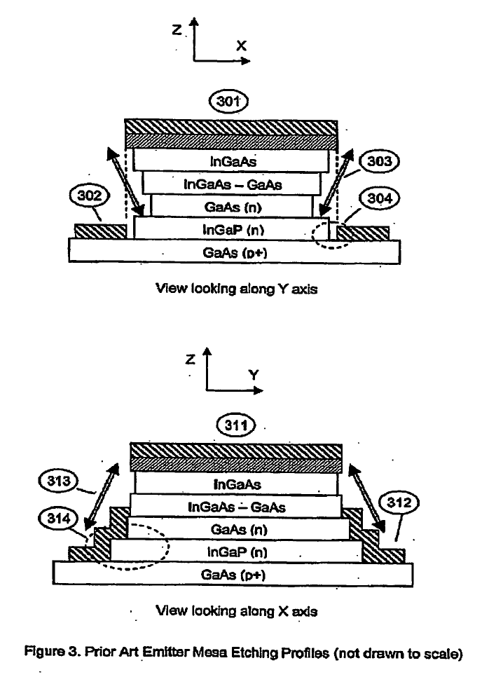

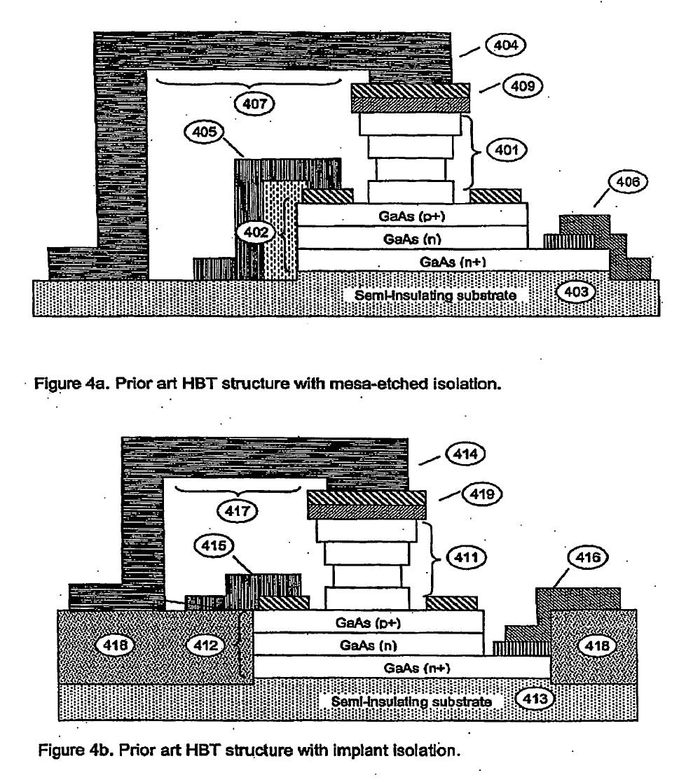

### DETAILED DESCRIPTION

In the following detailed description, reference is made to the accompanying drawings which form a part hereof, and in which is shown by way of illustration specific preferred embodiments in which the invention may be practiced. These embodiments are described in sufficient detail to enable those skilled in the art to practice the invention, and it is to be understood that other embodiments may be utilized and that structural, material and electrical changes may be made without departing from the scope of the present invention. The following detailed description is, therefore, not to be taken in a limiting sense, and the scope of the present invention is defined only by the appended claims.

According to the present invention, improved integrated circuits are provided. More particularly, the invention provides a method and structure for a high performance heterojunction bipolar transistor which is suited to compound semiconductor material systems such as gallium arsenide and which utilises an emitter junction formed from a plurality of metal layers and a plurality of ultra-thin insulating layers. The metal layers chosen have work-functions which form a tunnelling. Metal-Insulator-Semiconductor (MIS) emitter junction when deposited on top of an ultra-thin insulating layer. The insulating layer is made from a rare-earth oxide such as gadolinium oxide (Gd₂O₃) which is epitaxially grown on a compound semiconductor substrate and may also possibly be covered with a second ultra-thin insulating layer. Further details of the present invention can be found throughout the present specification and more particularly below.

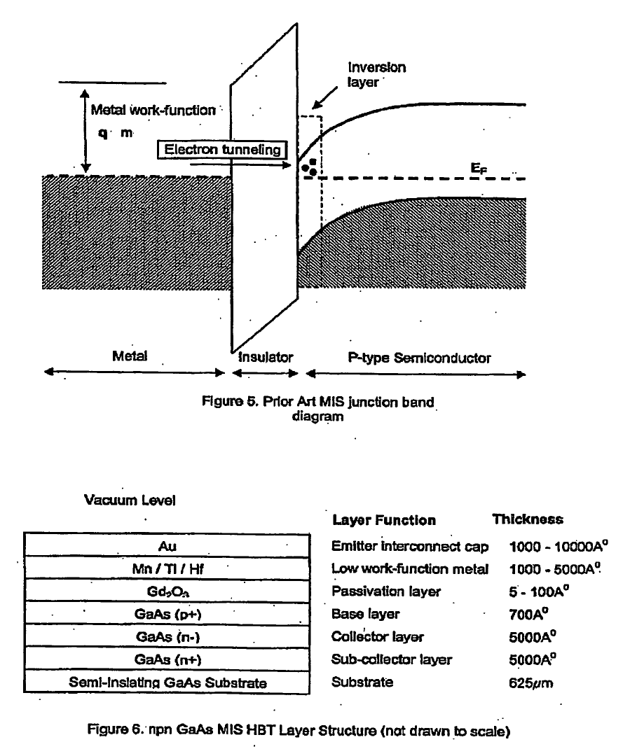

The present invention preferably uses compound semiconductor wafers with equivalent base, collector and sub-collector layers, as used in conventional devices, as shown in FIG. 6. Instead of the usual emitter structure, the present invention utilizes a thin insulating layer made from a rare earth oxide such as Gd₂O₃ to passivate the base layer. This insulating layer is preferably between 5 and 100 angstroms thick and is deposited by epitaxial growth techniques, such as molecular beam evaporation, onto the GaAs wafer as a mono-crystalline film.

A low work-function metal layer is deposited on top of the ultra-thin insulator to form the emitter layer of the device. This layer is preferably deposited onto a wafer during wafer patterning to produce devices and circuits. The composition of the metallic emitter layer is preferably chosen according to the following requirements:
1) it has a low work function, preferably less than 4.2 eV,
2) it provides good adhesion characteristics to the underlying insulator layer
3) it has a high melting temperature and does not readily diffuse through the insulating layer
4) it can be etched by chemicals which do not effect the underlying insulating layer
5) it has good electric conductivity
6) it has good long-term chemical stability

The metallic emitter layer is preferably made from a rare earth metal such as gadolinium, or manganese, titanium, hafnium or other similar low work function metals. It may also be made from a semi-metallic compound such as lanthanum sulphide, neodymium sulphide which offer very low electron work functions and good thermal and chemical stability. It may also be made from a plurality of elements in either an amorphous or layered structure to achieve the electrical, chemical or physical properties listed above. The emitter layer is preferably between 1000 and 5000 angstroms thick.

It should be understood that although the present invention is described herein with respect to an npn device structure for simplicity, the fundamental principles of the present invention apply equally to pnp devices. Accordingly, the present invention also provides a structure for pnp MIS HBT transistors. In these devices a high work function metal such as nickel, platinum or palladium is used for the emitter metal.

As shown in FIG. 6, the emitter layer is capped with a second metallic layer preferably made from materials which have:
1) high resistance to the chemical processes used to etch the low work-function emitter layer, and
2) high electric conductivity

The emitter cap layer is preferably gold and between 1000 and 10,000 angstroms thick. This layer is also preferably deposited onto a wafer using the same process step which deposits the low work-function emitter layer.

Additional layer may be incorporated between the emitter cap layer and the emitter layer to promote adhesion between the layers or to prevent inter-diffusion of the layers. Titanium and platinum may be used for these purposes respectively with thicknesses between 100 and 1000 angstroms.

From another aspect, the present invention provides a method of forming a self aligned emitter-base junction which minimises separation between base and emitter contacts and reduces base spreading resistance, preferably according to the following.

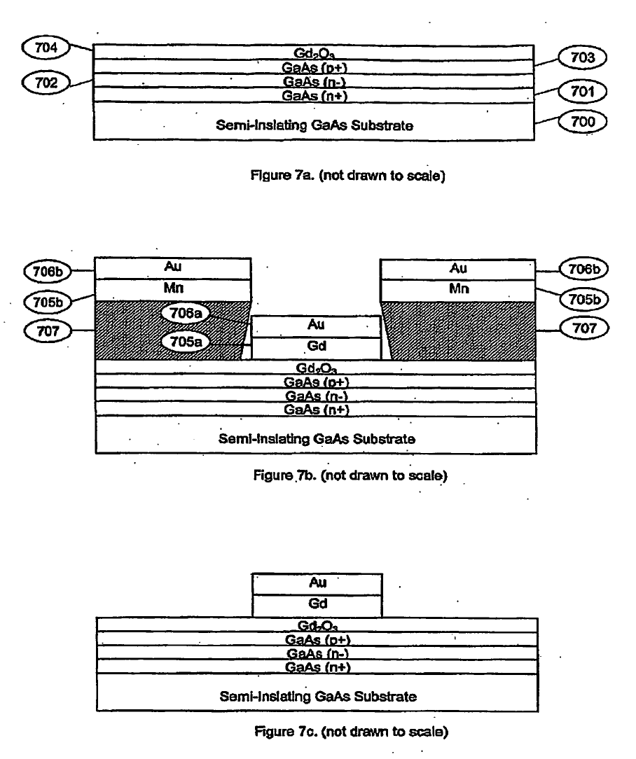

The process for making an npn MIS HBT transistor begins with a wafer with layer structure similar to FIG. 7a. Each of the device layers 701-704 are epitaxially deposited as a mono-crystalline structure. The emitter of the device is formed by sequentially depositing and patterning two layers of metal 705 and 706 on the surface of the wafer. This may be accomplished using techniques which are well known such as the lift-off process shown in FIG. 7b. In this process, photoresist 707 is deposited on the surface of the wafer and exposed and developed to create the profile shown. Metal layers 705 and 706 are deposited on top of the photoresist layer and form the emitter structure 705a, 706a. The photoresist is then dissolved thereby removing excess metal 705b, 706b to give the structure shown in FIG. 7c.

The main purpose of the emitter cap layer is to allow the emitter structure to be patterned by selective etching to produce an “undercut” profile around its periphery thereby allowing the transistor's base ohmic contact layer to be subsequently deposited in a self-aligned manner around the emitter. The secondary purpose of the emitter cap layer is to reduce lateral emitter resistance.

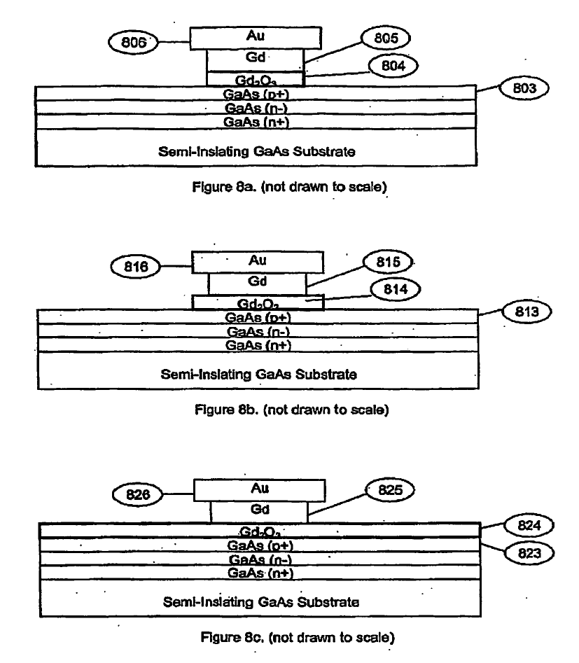

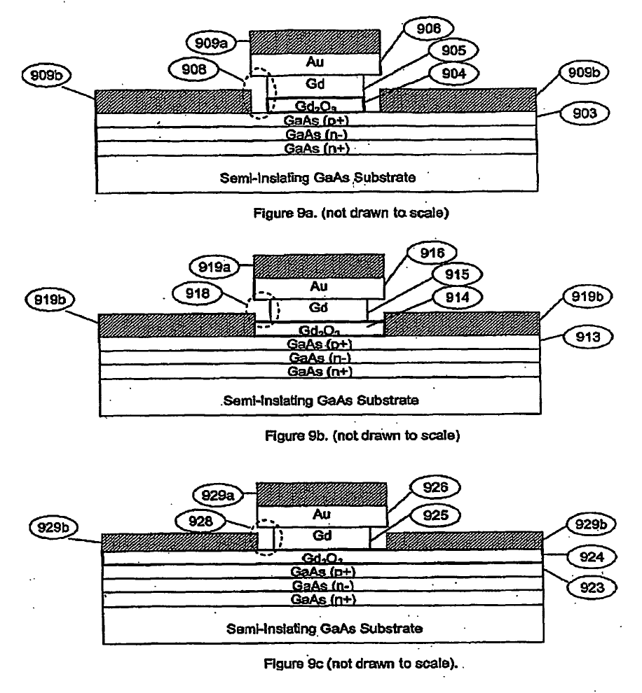

The process of depositing the base ohmic contact begins by undercutting the emitter structure as shown. In FIG. 8. This subsequently provides a lateral spacing between the side walls of the emitter layer and the base ohmic contact layer which is deposited later. The depth of this lateral etching is preferably around 1000 angstroms.

Three alternative emitter structures are shown in FIGS. 8a to 8c.

In FIG. 8a, an etchant is used to remove portions of the sides of the emitter layer 805 to create the desired undercut profile. The composition of emitter cap layer is chosen to resist this etching process thereby protecting the top surface of the emitter layer. It is preferably gold.

The etching process shown in FIG. 8a also removes exposed portions of the insulating layer 804 so that the base ohmic contact layer is subsequently deposited directly on the surface of the base layer 803. The etchant used to remove the insulating layer 804 is chosen to avoid etching of the underlying base layer 803.

A wet chemical process using an acid such as aqueous HCl or an alkali such as HN₄OH may be used for this purpose. Alternatively, a dry etch process using chlorine, fluorine or methyl-containing gaseous reactants may be used.

A combination of wet and dry etching processes may be used to achieve the alternative structure shown in FIG. 8b. Emitter layer 815 may be etched using a wet process as described above whereas the insulating layer 814 may be removed using a directional dry etching process. In this process the emitter cap layer 816 masks and protects insulating layer 814 from the directional etching process. The advantage of this process is that the insulating layer 814 passivates the surface of the base layer 813 between the emitter and base contacts and enhances current gain.

FIG. 8c shows a third alternative where only the emitter layer 825 is etched.

FIGS. 9a-c show base ohmic deposition for corresponding FIGS. 8a-c.

The base ohmic layer is deposited over the top of the emitter structures to form base contacts 909b/919b/929b. The emitter cap layers 906/916/926 masks the emitter layers 905/915/925 during this deposition process so that the base contacts have a lateral separation 908/918/928 from the emitter layers. This separation is preferably around 1000 angstroms.

The base ohmic contact layers 909a,b/919a,b/929a,b are preferably made from layers titanium/platinum/gold with respective thicknesses 200/200/2000 angstroms or platinum/titanium/platinum/gold with respective thicknesses 400/200/200/2000.

The present invention provides a simplified base ohmic connection as shown in FIG. 9c. The composition of the base ohmic contact layer 929a,b is chosen to provide a tunnelling contact to the base layer 923 through insulating layer 924. A high work-function metal such as platinum, nickel or palladium is deposited first for this purpose. This layer is preferably made from platinum/titanium/platinum/gold with respective thicknesses 400/200/200/2000 angstroms. The advantages of this approach are that the insulating layer 924 passivates the entire surface of the transistor and that etching requirements for the base-emitter junction are simplified.

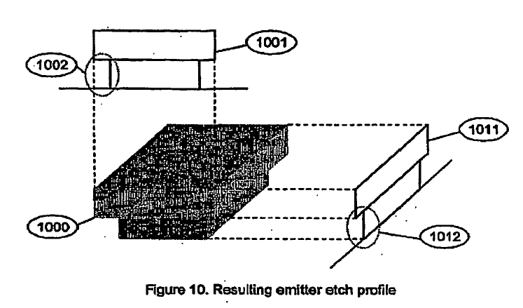

A benefit of the emitter structure of the present invention is that the etching profile of the emitter layer sidewalls is well controlled. As previously noted, the crystalline structure of conventional compound semiconductor HBT transistor emitters leads to relatively poor emitter etch profiles and reduced device fabrication yield. The present invention uses metals which are deposited in an amorphous or polycrystalline state and which have uniform etching characteristics in all dimensions. This is considered unique in the context of compound semi HBTs. This provides highly reproducible etching profiles 1002/1012 as shown in, FIG. 10 and high fabrication yields.

From another aspect, the present invention also provides a method of fabricating HBT transistors wherein the emitter layer of the transistor also provides means of interconnecting the emitter to other devices.

Since the emitter and emitter cap layers of the present invention are metallic, they can be used to interconnect the emitter to other devices. This avoids the need for a second, independent metallisation process to connect to emitter contacts to other conventional devices.

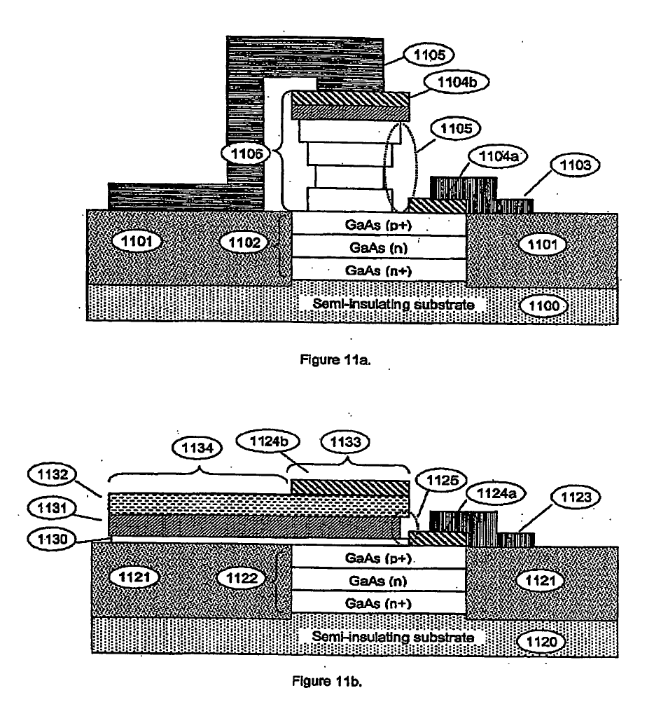

FIG. 11 a shows emitter and base connections of a conventional HBT. In order to reduce vertical profiles of devices, implantation is used to create device isolation regions 1101. Connection is typically made to the emitter contacts of devices 1104b by non-planar interconnects 1105 such as air-bridges. As previously noted, the size and alignment requirements of the emitter interconnect structures 1105 prevents conventional devices from being reduced in, size to improve their high frequency performance.

FIG. 11b shows the emitter and base contacts of the present invention. Implantation is used to form isolation regions 1121. Metal layers 1131 and 1132 form the emitter of HBT transistors in region 1133 as well as emitter interconnection features in region 1134. This means that the width of the emitter structure (perpendicular to the page as drawn) can be reduced below 1 micron and is limited only by the resolution of the lithography used to pattern the emitter metal layers. This significantly improves high frequency performance.

From another aspect, the present invention also provides a MIS HBT transistor structure incorporating a plurality of ultra-thin insulating layers, each having different composition and etching characteristics, onto which the emitter layer metal is deposited.

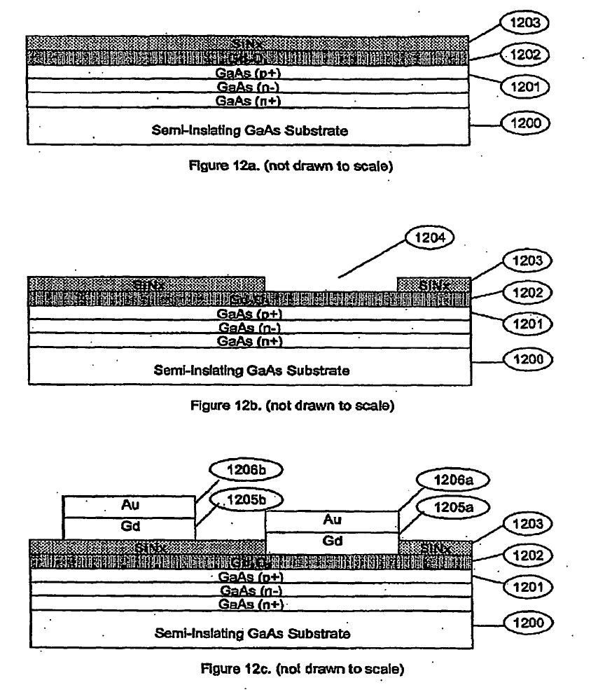

FIG. 12 shows a version of the present invention incorporating dual insulating layers.

In order to passivate the surface of the base layer 1201, the first insulating layer 1202 is epitaxially grown on the surface. This layer is preferably between 5 and 100 angstroms thick. A second insulating layer 1203 is deposited on the first layer within a similar range of thicknesses. It does not need to passivate the underlying layer and can be deposited in an amorphous or polycrystalline form. The composition of second layer 1203 is chosen to have different etching characteristics to the underlying layer 1202 so that it can be selectively removed without damaging this layer. The second layer 1203 is preferably silicon nitride or silicon dioxide.

Before depositing the emitter metals, holes 1204 are opened at certain locations in the upper insulating layer 1203. A dry etching process using fluorine containing reactants may be used for this purpose.

Emitter metals are then deposited to form emitter structures 1205a/1206a and 1205b/1206b. Because the two emitter structures have different overall thicknesses of insulating layer, the tunnelling characteristics of electrons will be different for the two transistors, allowing devices on the same wafer to be tailored to different characteristics. For example, devices with thicker insulating layers will launch electrons into the base at high energy levels such that they travel ballistically toward the collector, thereby increasing device operating frequency. However, this improvement may come at the cost of device power efficiency. Nevertheless, the present invention allows circuit designers to customise the performance of individual transistors on a single wafer for different applications.

While this invention has been described in connection with specific embodiments thereof, it will be understood that it is capable of further modification(s). This application is intended to cover any variations uses or adaptations of the invention following in general, the principles of the invention and including such departures from the present disclosure as come within known or customary practice within the art to which the invention pertains and as may be applied to the essential features hereinbefore set forth.

As the present invention may be embodied in several forms without departing from the spirit of the essential characteristics of the invention, it should be understood that the above described embodiments are not to limit the present invention unless otherwise specified, but rather should be construed broadly within the spirit and scope of the invention as defined in the appended claims. Various modifications and equivalent arrangements are intended to be included within the spirit and scope of the invention and appended claims. Therefore, the specific embodiments are to be understood to be illustrative of the many ways in which the principles of the present invention may be practiced. In the following claims, means-plus-function clauses are intended to cover structures as performing the defined function and not only structural equivalents, but also equivalent structures. For example, although a nail and a screw may not be structural equivalents in that a nail employs a cylindrical surface to secure wooden parts together, whereas a screw employs a helical surface to secure wooden parts together, in the environment of fastening wooden parts, a nail and a screw are equivalent structures.

“Comprises/comprising” when used in this specification is taken to specify the presence of stated features, integers, steps or components but does not preclude the presence or addition of one or more other features, integers, steps, components or groups thereof.” Thus, unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”.

1. A layered material arrangement adapted for use in a compound semiconductor metal-insulator-semiconductor device comprising an ultra-thin insulating layer.

2. The arrangement of claim 1, wherein the device is a bipolar transistor comprising an ultra-thin insulating layer made from a material having a bandgap of greater than 3 electron volts.

3. A metal-insulator-semiconductor transistor structure comprising:
III/V compound semiconductor material;
a layered material arrangement adapted for use in a compound semiconductor metal-insulator-semiconductor device including an ultra-thin insulating layer including a rare earth oxide coupled to the base layer;
a collector region;
a base layer coupled to the collector region; and
an emitter structure including a plurality of metal layers coupled to the ultra-thin insulating layer.

4. The structure of claim 3 wherein the emitter structure forms a part of an NPN transistor and comprises:
a low work-function metal layer coupled to the ultra-thin insulating layer; and
an emitter cap layer including a metal having different etch characteristics to the low work-function metal coupled to the low work-function metal layer.

5. The structure of claim 3 wherein the emitter structure forms a part of an PNP transistor and includes:
a high work-function metal layer coupled to the ultra-thin insulating layer; and
an emitter cap layer including a metal having different etch characteristics to the high work-function metal coupled to the high work-function metal layer.

6. The structure of claim 3 wherein the rare earth oxide has a form X₂O₃ where X is a rare earth element.

7. The structure of claim 6 where X is gadolinium.

8. The structure of claim 3 wherein the ultra thin insulating layer has a range in thickness of about 5 to about 100 Angstroms.

9. The structure of claim 3 wherein the ultra-thin insulating layer has a range in thickness of about 10 to about 20 Angstroms.

10. The structure of claim 4 wherein the emitter cap layer is selected from a gold material, a copper material, a silver material, and an aluminium material.

11. The structure of claim 10 wherein the emitter cap layer further comprises an adhesion layer between the low work-function metal layer and the emitter cap layer.

12. The structure of claim 11 wherein the adhesion layer is selected from titanium, nickel, chromium, and manganese.

13. The structure of claim 10 wherein the emitter cap layer further comprises a diffusion barrier layer between the low work-function metal layer and the emitter cap layer.

14. The structure of claim 11 wherein the adhesion layer is selected from platinum, palladium, tungsten or another refractory.

15. The structure of claim 3 wherein the emitter layer is selected from a rare earth metal such as gadolinium, manganese, titanium, hafnium, zirconium.

16. The structure of claim 3 wherein the rare earth oxide is epitaxially grown.

17. The structure of claim 3 wherein the rare earth oxide includes a crystal structure, the crystal structure being compatible with the base region.

18. The structure of claim 17 wherein the rare earth oxide is crystal matched to a material of the base region.

19. The structure of claim 3 wherein the rare earth oxide passivates surface states of a substantial portion of the base region.

20. The structure of claim 3 wherein the base region and the collector region are provided in a compound semiconductor material.

21. The structure of claim 3 wherein the emitter layer is undercut relative to the emitter cap layer.

22. The structure of claim 3 further comprising a base contact region overlying a portion of the base region, the base contact region extending toward the undercut of the emitter layer.

23. The structure of claim 22 wherein the base contact region provides a tunnelling contact to the base region through the ultra-thin insulating layer.

24. A method for manufacturing a metal-insulator-semiconductor transistor structure including III/V compound semiconductor material, the method comprising:
selectively depositing an emitter structure including an emitter layer and emitter cap layer overlying an ultra-thin insulating layer using a single process operation;
selectively removing at least a portion of the emitter layer while undercutting a portion of the emitter cap layer to reduce a width of the emitter layer; and
selectively depositing a base contact layer over both a base layer and emitter layer and cap regions to form a base contact, the base contact being self-aligned to the emitter structure.

25. The method of claim 24 wherein the ultra-thin insulating layer comprises a rare earth oxide.

26. A method for manufacturing a metal-insulator-semiconductor transistor structure including III/V compound semiconductor material, the method comprising:
providing a semiconductor substrate having a surface region;
forming a collector region within a portion of the substrate;
forming a base layer overlying the collector region;
forming a rare earth oxide layer overlying the base layer;
selectively depositing an emitter structure including an emitter layer and emitter cap layer using a single process operation overlying the rare earth oxide;
selectively removing at least a portion of the emitter layer while undercutting a portion of the emitter cap layer to reduce a width of the emitter layer; and
selectively depositing a base contact layer over both the base layer and the emitter structure to form a base contact, the base contact being self-aligned to the emitter structure.

27. The method of claim 25 wherein the selectively depositing includes a lift-off process.

28. The method of claim 25 wherein the selectively removing includes a selective etchant that selectively removes a portion of the emitter layer relative to a portion of the emitter cap layer.

29. The method of claim 28 wherein the etchant is aqueous or is provided via a wet process.

30. The method of claim 28 wherein the etchant is gaseous or is provided via a dry process.

31. The method of claim 28 wherein the etchant also removes the rare-earth oxide but maintains the underlying base layer.

32. The method of claim 25 further comprising removing the rare earth oxide using a directional dry etching technique to leave the oxide layer intact under the emitter cap layer.

33. The method of claim 32 wherein the directional etching technique is reactive ion etching.

34. The method of claim 25 wherein the base contact layer is deposited onto the rare earth oxide layer to form a low resistance metal-insulator-semiconductor junction.

35. The method of claim 34 wherein the base layer is p-type and a high work-function metal layer is coupled to the rare earth oxide layer.

36. The method of claim 35 wherein the high work function metal is selected from platinum, palladium, nickel or gold

37. The method of claim 34 wherein the base layer is n-type and a low work-function metal layer is coupled to the rare earth oxide layer.

38. The method of claim 37 wherein the low work function metal is selected from a rare earth metal such as gadolinium, manganese, titanium, hafnium, zirconium.

39. The method of claim 25 further comprising forming a secondary ultra-thin insulating layer overlying the rare earth oxide.

40. The method of claim 39 wherein the secondary insulating layer is selectively etched away while maintaining the rare-earth oxide layer.

41. The method of claim 40, wherein the etching is provided by a dry process.

42. The method of claim 40 wherein the secondary insulating layer is selected from silicon dioxide or silicon nitride

43. A method for manufacturing a metal-insulator-semiconductor transistor structure including III/V compound semiconductor material, the method comprising:
selectively implanting a semiconductor substrate with an ion which renders the semiconductor substrate insulating and forms isolation regions;
selectively depositing an emitter structure including an emitter layer and emitter cap layer in a single process operation overlying an ultra-thin insulating layer;
selectively removing at least a portion of the emitter layer while undercutting a portion of the emitter cap layer to reduce a width of the emitter layer; and
selectively depositing a base contact layer over both a base layer and the emitter structure to form a base contact which is self-aligned to the emitter structure.

44. A method for manufacturing a metal-insulator-semiconductor transistor structure including III/V compound semiconductor material, the method comprising:
providing a semiconductor substrate;
forming a collector region within the substrate;
forming a base layer overlying the collector region;
forming a rare earth oxide layer overlying the base layer;
selectively implanting the substrate with an ion which renders the substrate insulating and forms isolation regions;
selectively depositing an emitter layer and emitter cap layer in a single process operation overlying the rare earth oxide;
selectively removing at least a portion of the emitter layer while undercutting a portion of the emitter cap layer to reduce a width of the emitter layer; and
selectively depositing a base contact layer over both base and emitter regions to form a base contact which is self-aligned to the emitter structure.

45. The method of claim 43 wherein the implanted ion is oxygen

46. The method of claim 43 wherein the emitter layer forms both emitters of devices in non-implanted regions and interconnections for emitters elsewhere.

47. A method for manufacturing a MIS HBT transistor structure including III/V compound semiconductor material, the method comprising:
providing a semiconductor substrate;
forming a blanket collector region within the substrate;
forming a blanket base region overlying the collector region;
forming a blanket rare earth oxide overlying the base region; and
selectively implanting one or more regions to form one or more isolation regions.

48. A method for manufacturing a MIS HBT transistor structure including III/V compound semiconductor material, the method comprising:
providing a semiconductor substrate;
forming a collector region within the substrate;
forming a base region overlying the collector region;
forming a rare earth oxide overlying the base region;
forming a blanket emitter layer overlying the rate earth oxide;
forming a blanket emitter cap layer overlying the emitter layer; and
patterning at least the blanket emitter cap layer to define a first portion of one or more emitter structures and to define a second portion of one or more interconnect structures.

49. An apparatus adapted to manufacture a transistor structure, said apparatus including:
a processor adapted to operate in accordance with a predetermined instruction set,
said apparatus, in conjunction with said instruction set, being adapted to perform the method of
selectively depositing an emitter structure including an emitter layer and emitter cap layer overlying an ultra-thin insulating layer using a single process operation,
selectively removing at least a portion of the emitter layer while undercutting a portion of the emitter cap layer to reduce a width of the emitter layer: and
selectively depositing a base contact layer over both a base layer and emitter layer and cap regions to form a base contact, the base contact being self-aligned to the emitter structure.

50. A computer program product including:
a computer usable medium having computer readable program code and computer readable system code embodied on said medium for manufacturing a transistor structure within a data processing system,
computer readable code within said computer usable medium for performing the steps of
selectively depositing an emitter structure including an emitter layer and emitter cap layer overlying an ultra-thin insulating layer using a single process operation;
selectively removing at least a portion of the emitter layer while undercutting a portion of the emitter cap layer to reduce a width of the emitter layer: and
selectively depositing a base contact layer over both a base layer and emitter layer and cap regions to form a base contact, the base contact being self-aligned to the emitter structure.

51-52. (canceled)
